(19) United States
(12) Patent Application Publication
(10) Pub. No.: US 2025/0184667 A1
(43) Pub. Date: Jun. 5, 2025

(54) CORRUGATIONS OR WEAKENED REGIONS ON ARMATURE STRUCTURES OF VERTICAL MEMS CONVERTER MEMBRANES

(71) Applicant: Hahn-Schickard-Gesellschaft für angewandte Forschung e. V., Villingen-Schwenningen (DE)

(72) Inventors: Dennis Becker, Donaueschingen (DE); Alfons Dehé, Reutlingen (DE)

(21) Appl. No.: 18/842,000

(22) PCT Filed: Feb. 27, 2023
(86) PCT No.: PCT/EP2023/054827

§ 371 Date: Aug. 27, 2024

(30) Foreign Application Priority Data
Feb. 28, 2022 (EP) 22159198.5
Jun. 21, 2022 (EP) 22180187.1

(51) Int. Cl. H04R 7/10; H04R 17/02; H04R 31/00

(52) U.S. Cl. CPC H04R 7/10; H04R 17/02; H04R 31/003; H04R 2201/003

(57) ABSTRACT

In a first aspect, the invention relates to a MEMS transducer which comprises a vibratable membrane for generating or receiving pressure waves in a vertical emission direction, wherein the vibratable membrane is held by a carrier and the vibratable membrane exhibits vertical sections which are substantially parallel to the emission direction or reception direction and comprise at least one layer of an actuator material. The vibratable membrane is preferably in contact with an electrode at the end such that the vertical sections can be induced to vibrate horizontally by driving the electrode or such that an electrical signal can be generated at the electrode when the vertical sections are induced to vibrate horizontally. The vertical sections and/or the horizontal sections thereby exhibit one or more corrugations and/or weakened regions. In a further aspect, the invention relates to a method for producing the MEMS transducer according to the invention.

In a first aspect, the invention relates to a MEMS transducer which comprises a vibratable membrane for generating or receiving pressure waves in a vertical emission direction, wherein the vibratable membrane is held by a carrier and the vibratable membrane exhibits vertical sections which are substantially parallel to the emission direction or receiving direction and comprise at least one layer of an actuator material. The vibratable membrane is preferably in contact with an electrode at its end such that the vertical sections can be induced to vibrate horizontally by driving the electrode or such that an electrical signal can be generated at the electrode when the vertical sections are induced to vibrate horizontally. The vertical sections and/or the horizontal sections have one or more corrugations and/or weakened regions.

In a further aspect, the invention relates to a method of producing the MEMS transducer according to the invention.

### BACKGROUND AND PRIOR ART

Today, microsystems technology is used in many areas of application for the production of compact, mechanical-electronic devices. The microelectromechanical systems (MEMS) that can be produced in this way are very compact (approx. in the micrometer range) with outstanding functionality and ever lower production costs.

MEMS transducers, such as MEMS loudspeakers or MEMS microphones, are also known from the prior art. Current MEMS loudspeakers are usually designed as planar membrane systems with vertical actuation of a vibratable membrane in the direction of emission. They are induced to vibrate, for example, by means of piezoelectric, electromagnetic or electrostatic actuators.

Zou, Zhijian & Litian (1996) disclose a capacitive MEMS microphone comprising a thin, flexible membrane as the active electrode and a rigid backplate as the stationary electrode. To optimize the mechanical sensitivity of the membrane, corrugations are applied, which are connected to each other by flat sections (bridges). The introduction of the corrugations is intended in particular to reduce intrinsic stress in the membrane. A capacitive MEMS microphone is also disclosed in CN 112492487. Therein, the aim is to prevent unwanted adhesion between the membrane and a backplate. For this purpose, a section comprising protrusions is present on the membrane in order to prevent adhesion and thus ensure long-lasting functional suitability.

An electromagnetic MEMS speaker for mobile devices is described in Shahosseini et al. 2015. The MEMS speaker features a stiffening silicon microstructure as a sound radiator, with the movable part suspended from a carrier via silicon drivers to enable large out-of-plane displacements using an electromagnetic motor.

Stoppel et al. 2017 disclose a two-way loudspeaker whose concept is based on concentric piezoelectric actuators. As a special feature, the vibratable membrane is not closed, but comprises eight piezoelectric unimorph actuators, each consisting of a piezoelectric and a passive layer. The outer woofers consist of four trapezoidal actuators clamped on one side, while the inner tweeters are formed by four triangular actuators connected to a rigid frame by means of springs. The separation of the membrane is intended to allow an improved sound image with higher power.

A disadvantage of such planar MEMS loudspeakers is their limitation in terms of the possible sound power, particularly at low frequencies. One reason for this is that the sound pressure level that can be generated is proportional to the square of the frequency for a given displacement. Sufficient sound power therefore requires either displacements for the vibratable membranes of at least 100 μm or large-area membranes in the square centimeter range. Both conditions are difficult to achieve using MEMS technology.

In the prior art, it was therefore proposed to design MEMS loudspeakers that do not exhibit a closed membrane for vibrations in the vertical emission direction, but rather a large number of movable elements that can be induced to vibrate laterally or horizontally. The advantage of this is that an increased volume flow can be moved on a small surface area and thus an increased sound power can be provided.

A MEMS loudspeaker based on this principle is disclosed, for example, in US 2018/0179048 A1 and Kaiser et al. 2019.

The MEMS loudspeaker comprises a plurality of electrostatic bending actuators, which are arranged between a top and bottom wafer as vertical lamellae and can be induced to vibrate laterally by means of an appropriate drive. An inner lamella forms an actuator electrode opposite two outer lamellae. Apart from a connecting node of electrodes that are still galvanically separated, there is an air gap between the three curved lamellae. If a potential is applied from inside to outside, this causes an attraction on both sides due to the curvature of the design in a preferred direction, which is specified by an anchor. The convexity of the outer lamellae facilitates movability. The restoring force is provided by a mechanical spring force. Pull-push operation is therefore not possible.

Another disadvantage is that gaps between the bending actuators and the top/bottom wafers, which are necessary for their movability, lead to ventilation between the two chambers. This limits the lower limit frequency. Furthermore, the lateral movement of the bending actuators and therefore the sound power is restricted in order to avoid a pull-in effect and acoustic breakdown.

US 2017/0006381 A1 discloses a MEMS sound transducer comprising a multilayer piezoelectric membrane suspended between a carrier substrate. By providing an intermediate layer between two piezoelectric layers, the piezoelectric effect and thus the performance of the transducer as a microphone or loudspeaker is to be enhanced. The membrane is structured in such a way that there is a plurality of recesses where there is no piezo layer. Furthermore, the membrane has contact depressions with different depths such that the piezo layers can be induced and/or electronic signals can be received via a respective upper and lower electrode layer.

The recesses are intended to achieve greater travel in the z-direction and thus a higher sound pressure. The membrane is structured in such a way that a meandering pattern with active piezoelectric regions and passive piezoelectric regions is present in a plan view. The active piezoelectric regions (25a-d) preferably exhibit an anchorage to the carrier at the outer end of the membrane and a free end in the direction of the center of the membrane, such that the membrane can be moved or curved in an out-of-plane or z-direction.

An alternative air pulse or sound generation system based on MEMS is described in US 2019/011 64 17 A1. The apparatus comprises a front and rear chamber and a plurality of valves, the front and rear chambers being separated from each other by means of a folded membrane. In one embodiment, the folded membrane has a rectangular meander structure in cross-section with horizontal and vertical sections. Piezo actuators are positioned on the respective horizontal sections in order to cause lateral movement of the vertical sections by synchronized stretching or compression of the horizontal sections. With the proposed principle, an increased volume flow and thus a higher sound power can also be generated on a small chip surface.

However, the increased effort required for the synchronized drive of the piezo actuators is disadvantageous. There is also potential for improvement with regard to the volume displaced by the lateral vibrations, which is limited by the geometric arrangement of the unilaterally actuated horizontal sections.

WO 2021/144400 A1 discloses a MEMS transducer that can be used both as a MEMS loudspeaker and as a MEMS microphone. The MEMS transducer described therein has a vibratable membrane which is constructed in such a way that it comprises two or more vertical sections which are substantially parallel to the vertical direction. Furthermore, the vibratable membrane comprises at least one layer of actuator material and at its end is in contact with at least one electrode. This allows the vertical sections to be induced to vibrate horizontally by activating the electrode. Conversely, an electrical signal can also be generated at the electrode when the vertical sections are induced to vibrate horizontally.

The MEMS transducer disclosed in WO 2021/144400 A1 exhibits significant improvements over the prior art. In the case of a MEMS loudspeaker, the design of the vibratable membrane comprising the vertical sections advantageously entails higher sound power, wherein the contacting simultaneously ensures simplified drivability. In the case of a MEMS microphone, a higher performance and audio quality with a suitable sound image is also advantageously made possible. In addition, proven semiconductor processing methods can be used to produce the MEMS transducer, enabling cost-efficient production.

Even though the MEMS transducer disclosed in WO 2021/144400 A1 represents an advanced further development of the prior art, there is potential for optimization in terms of performance and sound characteristics.

In light of the prior art, there is therefore still a need for the provision of improved MEMS transducers or methods for their production.

### OBJECTIVE OF THE INVENTION

The objective of the invention is to provide a MEMS transducer and a method for producing the MEMS transducer which do not exhibit the disadvantages of the prior art. In particular, one objective of the invention was to provide a MEMS transducer with high performance and sound quality, which at the same time is characterized by a simple, cost-effective and compact design.

### SUMMARY OF THE INVENTION

The objective of the invention is solved by the features of the independent claims. Preferred embodiments of the invention are described in the dependent claims.

In a first aspect, the invention preferably relates to a MEMS transducer for interacting with a volume flow of a fluid comprising a carrier and a vibratable membrane for generating or receiving pressure waves of the fluid in a vertical direction, which is attached to the carrier and is in contact with at least one electrode,
wherein the vibratable membrane exhibits vertical sections and horizontal sections, the vertical sections being substantially parallel to the vertical direction and the horizontal sections connecting the vertical sections to each other,
such that the vertical sections can be induced to vibrate horizontally by driving the at least one electrode or such that an electrical signal can be generated at the electrode when the vertical sections are induced to vibrate horizontally, characterized in that the vertical sections and/or the horizontal sections exhibit one or more corrugations and/or weakened regions.

In preferred embodiments, the MEMS transducer can be a MEMS loudspeaker or a MEMS microphone. Due to the design of the MEMS transducer, a number of advantages can be achieved both for use as a MEMS loudspeaker and as a MEMS microphone.

In particular, a MEMS loudspeaker with high sound power and simplified drive can be obtained. In contrast to known planar MEMS loudspeakers, the vibratable membrane itself does not have to be operated over a large area of several square centimeters or with a large displacement in order to generate sufficient sound pressure. Instead, the majority of the vertical sections of the vibratable membrane can move an enlarged total volume in the vertical emission direction with small horizontal or lateral movements of a few micrometers.

At the same time, simplified drive can be achieved. Whereas in the prior art, such as in US 2019/011 64 17 A1, a plurality of piezoelectric actuators have to be in contact with the horizontal sections, the MEMS loudspeaker described here can be operated by means of at least one electrode, preferably at the end. This reduces the production effort, minimizes sources of error and also inherently entails synchronous drive of the vertical sections for generating horizontal vibrations.

In this way, the air volumes present between the vertical sections can be moved extremely precisely along the vertical emission direction by the horizontal vibrations.

This also makes it possible to provide a particularly powerful MEMS microphone with high audio quality. The structure of the MEMS microphone is structurally similar to that of the MEMS loudspeaker, particularly with regard to the design of the vibratable membrane. However, instead of driving the electrodes to generate horizontal vibrations and thus sound pressure waves, the MEMS microphone is designed to receive sound pressure waves in the same vertical direction. Preferably, there are volumes of air between the vertical sections, which are moved along a vertical detection direction when sound waves are received. The sound pressure waves cause the vertical sections to vibrate horizontally, such that the actuator material generates a corresponding periodic electrical signal.

Preferably, the MEMS transducer comprises a substantially continuous actuator layer comprising an actuator material. In particular, the actuator layer runs along the vertical sections and the horizontal sections of the membrane. It is therefore preferred that the vertical and horizontal sections comprise an actuator material. A substantially continuous actuator layer preferably means that the actuator layer is only interrupted by corrugation and/or weakened regions, but is otherwise present over the entire surface of the vibratable membrane. As explained in detail herein, the actuator layer is preferably used to induce the membrane to vibrate (in the case of a loudspeaker) or to detect vibrations of the membrane (in the case of a microphone), whereby the excitation or measurement principle differs significantly from capacitive MEMS transducers.

The application of corrugations and/or weakened regions on the vertical and/or horizontal sections has proven to be extremely advantageous for the vibrational behavior of the membrane, both with regard to uses as a MEMS loudspeaker and as a MEMS microphone.

According to the invention, it has been recognized that corrugations and/or weakened regions enable a higher degree of rotation of the vertical sections, whereby a particularly efficient displacement of the membrane is ensured during the generation or reception of pressure waves of the fluid. In particular, the corrugations and/or weakened regions cause the vertical sections to undergo a particularly defined curvature during the generation or reception of pressure waves and potentially irregular buckling is prevented particularly effectively.

When generating or receiving pressure waves, the vertical sections can therefore be driven or induced to vibrate horizontally even more effectively in order to optimize the performance of the MEMS transducer.

In this respect, it is a further advantage that the corrugations and/or weakened regions allow higher amplitudes of the horizontal vibrations of the vertical sections.

In the case of a MEMS loudspeaker, for example, this results in a higher displacement of the fluid volume between the vertical sections, which enables an increase in the generated sound pressure level. This results in a further improvement in terms of sound power, in particular the sound pressure level, compared to previous approaches. Accordingly, in the case of a MEMS microphone, more fluid volume can be received between the vertical sections and the sensitivity of the sound detector can be increased.

It is also advantageous that a particularly uniform curvature of the vertical sections in both directions of the horizontal vibrations is made possible. This can reduce harmonic distortion, in particular the THD (total harmonic disorder). The THD preferably indicates the ratio of the summed power of all harmonics to the power of the fundamental oscillation of a vibratable membrane. Consequently, by reducing the THD, the sum of the harmonics and therefore the distortion of the measured signal or the signal that can be generated is reduced. This results in a particularly good sound image both when receiving and when generating pressure waves of the fluid.

By introducing irregularities in the form of corrugations and/or weakened regions into the vibratable membrane, its vibrational behavior is therefore surprisingly not distorted, but rather harmonized.

The advantageous effects can be attributed in part to the fact that a rigidity of the respective sections of the vibratable membrane can be adjusted by means of the corrugations and/or weakened regions. For example, it was recognized in accordance with the invention that horizontal sections that are too rigid can adversely impede the movability of the vertical sections and lead to irregularities in their displacement or curvature during horizontal vibrations. Targeted positioning of corrugations and/or weakened regions, in particular in the horizontal sections, reduces their rigidity and increases the displacement capacity or freedom of rotation of the vertical sections.

In this way, the rigidity and thus the displacement capacity can be advantageously adjusted by means of the design of the corrugations and/or the weakened regions, in particular with regard to geometry, width and/or depth, and adapted depending on the application.

It was found that both corrugations and weakened regions result in the advantageous technical effects described above. Consequently, in addition to the design of the corrugations, the vibration behavior of the vibratable membrane of the MEMS transducer can also be optimized by means of preferred embodiments of the weakened regions, for example with regard to a variation of layer thicknesses, number or positioning.

In addition, the provision of corrugations and/or weakened regions is possible using known techniques, process steps and/or methods of semiconductor and microsystem technology, which have established themselves as particularly effective in the prior art. Thus, the application of corrugations and/or weakened regions on the vertical and/or horizontal sections is advantageously possible in a process-efficient manner.

A corrugation preferably denotes a deviation from a course of a partial section of the vibratable membrane, wherein said deviation is preferably a depression or elevation in an otherwise essentially planar course of the partial section. In a cross-sectional view of the vibratable membrane, a corrugation preferably characterizes a deviation from a continuous, preferably rectilinear course of a partial section (e.g. a horizontal and/or vertical partial section). For example, a corrugation can refer to a groove or furrow or a ridge, i.e. in particular a depression or elevation in the vertical and/or horizontal sections. These corrugations can have a plurality of configurations in terms of geometry, depth, width and/or aspect ratio.

A weakened region preferably refers to a reduction in the thickness of a layer of the vibratable membrane. Preferably, weakened regions refer to thicknesses of the layers providing the vertical and/or the horizontal sections. For example, the horizontal sections and/or vertical sections may be multi-layered and wherein one or more weakened regions are caused by a variation of the layer thickness of at least one layer. Preferably, the layer thickness of the at least one layer (e.g. an actuator layer, the layer of an electrically conductive layer or a top or bottom electrode or a mechanical support layer) is reduced to less than 70%, preferably less than 60%, 50%, 40% or less of an initial layer thickness. A weakened region can also mean a reduction of a layer thickness of at least one layer to 30%, 20% or 10% or less of an initial layer thickness. The terms “layer” and “stratum” can be used synonymously in the context of the invention.

A corrugation and/or a weakened region is preferably present in the vertical and/or horizontal sections, wherein preferably a plurality of corrugations and/or weakened regions can also be present along a section.

It may also be preferred that a weakened region corresponds to a reduction of a layer thickness of at least one layer to 0% of an initial layer thickness. Thus, it may be preferred that a weakened region is characterized by the absence of the at least one layer in a partial region of the membrane. Preferably, a weakened region is characterized by a reduction of a layer thickness of at least one layer (in some embodiments to 0%), wherein at least one other layer in the weakened region has no reduction in layer thickness compared to an initial layer thickness. In some embodiments, however, a weakened region can also be characterized by a reduction in the layer thickness of all layers of the membrane, up to the absence of all layers in a partial region. In the latter case, an weakened region is preferably formed by an opening in the membrane.

Furthermore, it may also be preferred that a weakened region is characterized by an exchange of the at least one layer for another layer (i.e. a layer comprising another material). For example, a weakened region can be formed by exchanging an actuator material in a partial area for a non-actuator material or insulation material, preferably an insulation layer or insulation stratum. As shown in more detail below, a weakened region can therefore be achieved both by a weakening of the mechanical properties of a partial region (e.g. reduction of rigidity) and by a weakening of a functional property, e.g. the ability to be induced to change shape by application of a signal.

Preferably, weakened regions and corrugations may be present in combination with each other on the membrane. For example, it may be preferred that a weakened region is present along a partial section of the membrane to which a corrugation is also applied, wherein the partial section is, for example, a vertical and/or a horizontal section of the membrane. Likewise, it may be preferred that a weakened region is present at or within a corrugation. That is, it may be preferred that a weakened region is present within a corrugation, for example in the form of a reduction of a layer thickness of at least one layer relative to an initial layer thickness (in some cases to 0%). It may also be preferable for a corrugation to be present within a weakened region. In other words, the weakened region may, for example, extend over a partial section of the membrane, with additional corrugation, as described above, being introduced within the weakened partial section.

Both weakened regions and corrugations are preferably characterized by the fact that they represent a deviation or inhomogeneity with regard to the functional and/or mechanical properties of the partial sections of the vibratable membrane, which is, however, deliberately introduced. The inventors have recognized that by deliberately introducing corrugations and/or weakened regions into horizontal and/or vertical sections, a displacement capacity of the vertical sections and thus the vibration behavior of the vibratable membrane can be considerably improved.

Preferably, a weakened region is therefore characterized by a change in the functional and/or mechanical properties of a partial section or partial region of the membrane.

A functional property can preferably mean an adaptation of the actuation capacity of the partial section, such that in particular a weaker actuation takes place at the weakened region than at partial sections of the membrane that do not have a weakened region. For this purpose, it may be preferable for the layer thickness of the actuator layer to be reduced or completely absent in the weakened region. It may also be preferable for a layer necessary for driving the actuator layer, such as a layer of conductive material, to be omitted in some areas or only present in a reduced form.

In the case of an actuator layer formed from a piezoelectric material, a weaker actuation capacity can be ensured, for example, by reducing the occurrence of a piezoelectric effect at a partial section of the membrane. For example, it may be preferable to introduce a dielectric insulation layer in the section between a piezoelectric actuator layer or to omit a driving top or bottom electrode in some areas. While the membrane is being induced to vibrate, the actuator layer will therefore experience no or only a reduced change in voltage or shape in the weakened region. The occurrence of buckling or other distortions can be surprisingly effectively prevented by deliberately introducing irregularities in the actuation of the sections in this way. The vertical sections in particular can exhibit increased movability and vibrate harmoniously—without distortion.

A weakened region can also be characterized by a change, in particular a reduction, in the mechanical properties of the membrane in the relevant section. Mechanical properties means, for example, rigidity, i.e. a property of mechanically resisting a change in shape. Preferably, mechanical properties of a weakened region can be achieved, for example, by reducing the layer thickness of a mechanical support layer or by replacing a layer of a mechanical support material with a material with a lower rigidity (or a higher modulus of elasticity). The partial weakening of the mechanical properties, such as the rigidity of the membrane, also advantageously entails an optimization of the displacement behavior of the membrane, in which the movability of the vertical sections is increased and undesirable effects such as buckling are avoided.

The directional indications vertical and horizontal with respect to the MEMS transducer or the membrane preferably refer to a preferred direction in which the vibratable membrane is oriented for generating or absorbing pressure waves of the fluid. Preferably, the vibratable membrane is suspended horizontally between at least two lateral regions of a carrier, while the vertical direction (direction of interaction with the fluid) for generating or receiving pressure waves is orthogonal to this.

In preferred embodiments, the MEMS transducer is a MEMS loudspeaker or a MEMS microphone. The term MEMS transducer thus refers to both a MEMS microphone and a MEMS loudspeaker. In general, the MEMS transducer refers to a transducer for interacting with a volume flow of a fluid that is based on MEMS technology and whose structures for interacting with the volume flow or for absorbing or generating pressure waves of the fluid have dimensions in the micrometer range (1 μm to 1000 μm). The fluid can be either a gaseous or a liquid fluid. The structures of the MEMS transducer, in particular the vibratable membrane, are designed to generate or receive pressure waves of the fluid.

For example, as in the case of a MEMS loudspeaker or MEMS microphone, these can be sound pressure waves. However, the MEMS transducer can also be suitable as an actuator or sensor for other pressure waves. The MEMS transducer is therefore preferably a device that converts pressure waves (e.g. acoustic signals as alternating sound pressures) into electrical signals or vice versa (conversion of electrical signals into pressure waves, for example acoustic signals).

In the case of a MEMS loudspeaker, the vertical (interaction) direction corresponds to the vertical sound emission direction of the MEMS loudspeaker. In this case, vertical preferably means the direction of sound emission, while horizontal means a direction orthogonal to it.

In the case of a MEMS microphone, the vertical (interaction) direction corresponds to the vertical sound detection direction of the MEMS microphone. In this case, vertical preferably means the direction of sound detection or recording, while horizontal means a direction orthogonal to this.

The vertical sections of the vibratable membrane thus preferably denote sections of the vibratable membrane which are essentially aligned in the emission direction of a MEMS loudspeaker or detection direction of a MEMS microphone. The person skilled in the art understands that this need not be an exact vertical alignment, but preferably the vertical sections of the vibratable membrane are aligned substantially in the emission direction of a MEMS loudspeaker or detection direction of a MEMS microphone.

In a preferred embodiment, the vertical sections are aligned substantially parallel to the vertical direction, wherein substantially parallel means a tolerance range of ±30°, preferably ±20°, particularly preferably ±10° around the vertical direction.

The vibratable membrane can therefore preferably not only have a rectangular meander shape in cross-section, but also a curved or wavy shape or a sawtooth shape (zigzag shape).

Preferably, the vertical and/or horizontal sections are straight at least in sections or over their entire length, but the vertical and/or horizontal sections can also be curved at least in sections or over their entire length. In the case of a curved shape of the vibratable membrane in cross-section, the alignment preferably relates to a tangent to the curved vertical and/or horizontal sections at their respective centers.

While the vibratable membrane is preferably aligned horizontally to the sound emission direction or sound detection direction, the sound waves are generated or, conversely, detected by actuation of the vertical sections. Preferably, therefore, at least the vertical sections comprise a layer comprising an actuator material.

For the purposes of the invention, the vertical and/or horizontal sections of the membrane preferably denote sections of a membrane (surface) which have different orientations. While the vertical sections of the membrane are essentially oriented in the direction of sound emission or sound detection, the horizontal sections of the membrane are essentially in an orientation orthogonal thereto. The membrane can thus also be understood as a folded membrane, the folding of which preferably takes place along a width. While the vertical and horizontal sections have a different orientation, they are preferably characterized by a similar layer structure and by layer thicknesses of essentially the same size. Preferably, functional layers of the membrane, such as an actuator layer, mechanical support layer and/or a layer comprising an electrically conductive material, also extend along both the horizontal and vertical sections. In this respect, the membrane according to the invention with horizontal and/or vertical sections differs significantly from the membrane disclosed in US 2017/0006381 A1. The membrane for the MEMS transducer disclosed in US 2017/0006381 A1 is instead a planar membrane, which is present in one plane and has no folding into vertical or horizontal sections. Accordingly, in the case of a configuration as a loudspeaker, the membrane of US 2017/0006381 A1 is induced to vibrate vertically along the direction of emission by excitation of the piezoelectric layers. In the case of a configuration as a microphone, sound waves are translated into vertical (out-of-plane) vibrations of the membrane along a detection direction, which can be read out by means of the piezoelectric layers. However, a folded membrane with vertical and horizontal sections, in which the vertical sections are induced to horizontal vibrations, i.e. orthogonal to the direction of emission or detection, is not disclosed. In contrast to the planar membrane of US 2017/0006381 A1, the vertical sections of a membrane according to the invention are induced to vibrate horizontally, whereby in particular fluid volumes located between the vertical sections are set into a flow. As explained at the beginning, in the case of a MEMS loudspeaker, an increase in the generated sound pressure level can be advantageously achieved compared to planar membranes due to a greater displacement of the fluid volume. In the case of a MEMS microphone, the folded design of the membrane can absorb more fluid volume between the vertical sections and increase the sensitivity of the sound detector.

In a preferred embodiment of the invention, the support comprises two lateral regions between which the vibratable membrane is arranged in a horizontal direction.

The carrier is preferably a frame structure, which is substantially formed by a continuous outer border in the form of side walls of a free planar area. The frame structure is preferably stable and rigid. In the case of an angular frame shape (triangular, square, hexagonal or generally polygonal outline), the individual side areas, which preferably substantially form the frame structure, are referred to in particular as side walls.

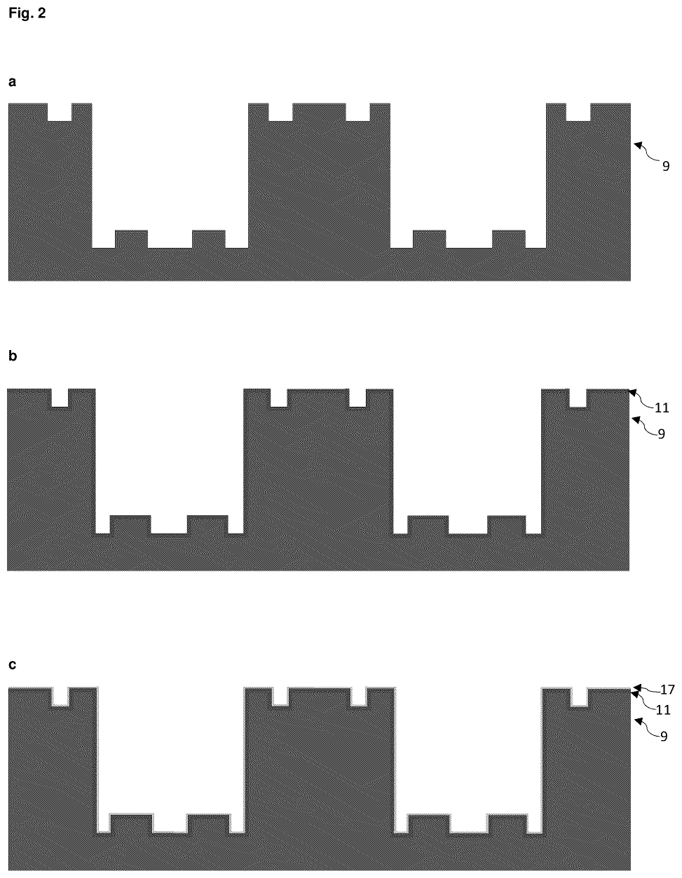

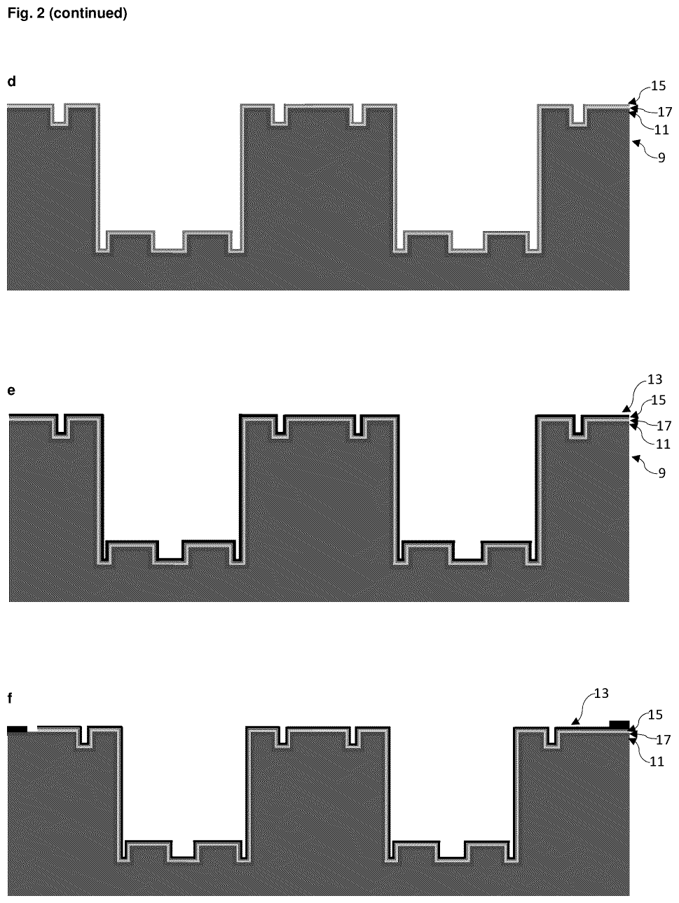

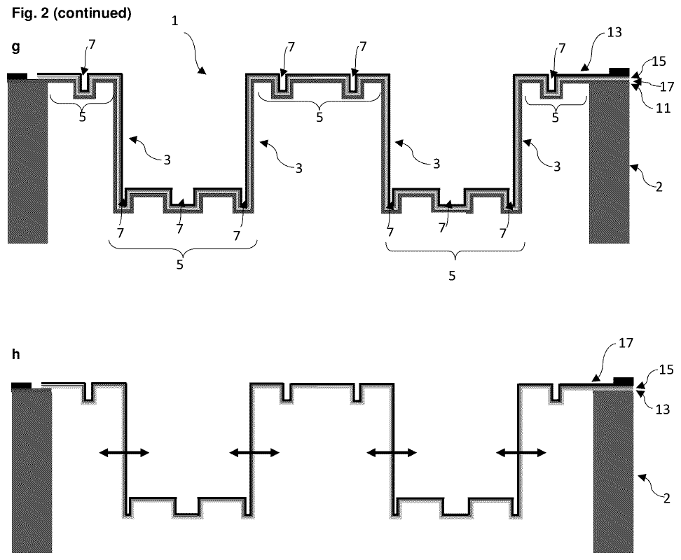

The vibratable membrane is preferably held by at least two side walls of the support. In the example in FIG. 2h, the two side walls can be seen in cross-section. Preferably, however, the carrier comprises four lateral regions, preferably with additional end faces generally parallel to the cross-section shown. These additional two side walls span the frame structure.

The vibratable membrane is preferably suspended in a planar manner within the free area. The planar extension of the vibratable membrane is characterized by a horizontal direction, while the vertical sections are substantially orthogonal thereto. In relation to the end faces, the membrane can be attached to these side walls or slotted there for greater movability. Advantageously, the slit can represent a dynamic high-pass filter which, for example, couples a front volume and rear volume together.

In a preferred embodiment of the invention, the carrier is formed from a substrate, preferably selected from a group comprising monocrystalline silicon, polysilicon, silicon dioxide, silicon carbide, silicon germanium, silicon nitride, nitride, germanium, carbon, gallium arsenide, gallium nitride, indium phosphide and/or glass.

These materials are easy and inexpensive to process in semiconductor and/or microsystem production and are suitable for large-scale production. The carrier structure can be produced flexibly due to the materials and/or production methods. In particular, it is preferably possible to produce the MEMS transducer comprising a vibratable membrane together with a carrier in a (semiconductor) process, preferably on a wafer. This further simplifies and reduces the cost of production, such that a compact and robust MEMS transducer can be provided at low cost.

Preferably, the at least one electrode is positioned at the end so that contact can be made with electronics, e.g. to a current or voltage source in the case of a MEMS loudspeaker, at one end of the vibratable membrane, preferably at an end at which the membrane is fixed to the carrier. Electrode preferably means an area made of a conductive material (preferably a metal) which is configured for making contact with electronics, e.g. a current and/or voltage source in the case of a MEMS loudspeaker. Preferably, it can be an electrode pad. Particularly preferably, the electrode pad is used for making contact with electronics and is itself connected to a conductive metal layer, which can extend over the entire surface of the vibratable membrane. In the following, the conductive layer together with an electrode pad is sometimes referred to as an electrode, for example as a top electrode or bottom electrode.

The layer of conductive material, preferably metal, in the sense of a top or bottom electrode is particularly preferred as a continuous or fully covering or continuous layer of the vibratable membrane, which forms a substantially homogeneous area and in particular is not structured. Instead, the two or more vertical sections are preferably in contact with the end-side electrode or the electrode pad by means of an unstructured layer of a conductive material, preferably metal.

In preferred embodiments, the MEMS transducer comprises two end electrodes. Preferably, contact with electronics, e.g. a current or voltage source, can be made with the electrodes at opposite ends of the vibratable membrane between which the vertical sections are present, so that the actuator layer(s) in the vertical sections can be driven by means of the end-side electrodes.

The end-side provision of the electrodes is thus preferably distinguished from contacts, which drive the respective vertical sections with separate electrodes or, in the case of a MEMS microphone, receives generated electrical signals. Preferably, the MEMS transducer thus comprises exactly one or exactly two electrodes for end-side contacts and no further electrodes (pads) for making contact with central vertical sections.

Preferably, the layer of an actuator material in the vertical sections serves as a component of a mechanical bimorph, wherein a lateral curvature of the vertical sections is caused by driving the actuator layer via the electrode or wherein a corresponding electrical signal is generated by an induced lateral curvature. It has proven to be extremely helpful for the performance of the mechanical bimorph that corrugations and/or weakened regions are present at vertical, horizontal and/or at connection points between vertical and horizontal areas.

In a preferred embodiment, the two or more vertical sections exhibit at least two layers, wherein one layer comprises an actuator material and a second layer comprises a mechanical support material, and wherein at least the layer comprising the actuator material is in contact with an end-side electrode, such that the horizontal vibrations can be generated by a change in shape of the actuator material relative to the mechanical support material. In the embodiment, the mechanical bimorph is formed by a layer of actuator material (e.g. a piezoelectric material) and a passive layer, which acts as a mechanical support layer. Both a transverse and longitudinal piezoelectric effect can be used for the bending.

When the actuator layer is driven, it can undergo transverse or longitudinal stretching or compression, for example. This creates a stress gradient in relation to the mechanical support layer, which leads to a lateral curvature or vibration. By alternating the polarity of the electrodes, a push-pull operation can preferably be achieved, whereby almost the entire air volume can be moved alternately between the vertical sections in the vertical emission direction. The corrugations and/or weakened regions allow a particularly high displacement of the vertical sections in this respect and therefore increase the displacement volume.

The advantage of the actuator principle is thus a highly efficient translation of the horizontal vibrations of vertical sections into a vertical volume movement or sound generation. This can be particularly optimized with the help of corrugations and/or weakened regions, as both the bending rigidity of the vertical sections and their freedom of rotation can be adjusted.

As the actuator principle is not based on electrostatic attraction, but on a relative change in shape (e.g. compression, stretching and/or shearing) of the actuator layer in relation to a support layer, it is not possible for the membrane sections to stick together. Instead, the vertical sections can touch each other at their ends and are therefore not restricted in their displacement.

In a further preferred embodiment, the two or more vertical sections comprise at least two layers, wherein both layers comprise an actuator material and are preferably in contact with electrodes at the ends and the horizontal vibrations can be generated by a change in shape of one layer relative to the other layer. In the embodiment, the horizontal vibration of the vertical sections is therefore not generated by a stress gradient between an active actuator layer and a passive support layer, but by a relative change in shape of two active actuator layers.

The actuator layers can consist of the same actuator material and be driven differently. The actuator layers can also consist of different actuator materials, for example piezoelectric materials with different deformation coefficients.

For the purposes of the invention, the “layer comprising an actuator material” is preferably also referred to as an actuator layer. An actuator material preferably means a material which undergoes a change in shape, for example stretching, compression or shear, when an electrical voltage is applied or, conversely, generates an electrical voltage when the shape is changed.

Materials are preferred with electric dipoles, which undergo a change in shape when an electric voltage is applied, wherein the orientation of the dipoles and/or the electric field can determine the preferred direction of the changes in shape.

Preferably, the actuator material can be a piezoelectric material, a polymer piezoelectric material and/or electroactive polymers (EAP).

Particularly preferred is a piezoelectric material selected from a group comprising lead zirconate titanate (PZT), aluminum nitride (AlN), aluminum scandium nitride (AlScN) and zinc oxide (ZnO).

For the purposes of the invention, the “layer comprising a mechanical support material” is preferably also referred to as a support layer. The mechanical support material or the support layer preferably serves as a passive layer which can resist a change in shape of the actuator layer. In contrast to an actuator layer, the mechanical support material preferably does not change its shape when an electrical voltage is applied. Preferably, the mechanical support material is electrically conductive such that it can also be used directly for making contact with the actuator layer. However, it can also be non-conductive in some embodiments and, for example, be coated with an electrically conductive layer.

The mechanical support material is particularly preferably monocrystalline silicon, polysilicon or doped polysilicon.

While the actuator layer undergoes a change in shape when an electrical voltage is applied, the layer of mechanical support material remains essentially unchanged. The resulting stress gradient between the two layers (mechanical bimorph) preferably causes a horizontal curvature. For this purpose, the thickness of the support layer should preferably be selected in comparison to the thickness of the actuator layer such that a sufficiently large stress gradient is generated for the curvature. For doped polysilicon as a mechanical support material and a piezoelectric material such as PZT or AlN, for example, thicknesses of substantially the same size, preferably between 0.5 μm and 2 μm, have proven to be particularly suitable.

Terms such as substantially, around, about, approx. etc. preferably describe a tolerance range of less than ±20%, preferably less than ±10%, even more preferably less than ±5% and in particular less than ±1%. Terms such as substantially, around, about, approx. etc. always disclose and include the exact stated value.

Contact with the actuator layer and/or the layer made of a mechanical support material, and thus application of an electrical voltage, can be achieved directly via electrodes at the ends or supported by a layer made of a conductive material.

In a preferred embodiment, the vibratable membrane therefore comprises at least one layer made of a conductive material.

In preferred embodiments, the conductive material is selected from a group comprising platinum, tungsten, (doped) tin oxide, monocrystalline silicon, polysilicon, molybdenum, titanium, tantalum, titanium-tungsten alloy, metal silicide, aluminum, graphite and/or copper.

The introduction of corrugations and/or the weakened regions according to the invention can equally relate to layers of an actuator material, a mechanical support material and/or a conductive material.

In a preferred embodiment, the MEMS transducer is characterized in that the one or more corrugations and/or weakened regions are present along the horizontal sections, along the vertical sections and/or at connection points between vertical sections and horizontal sections.

For example, it may be preferred to apply the corrugations and/or weakened regions only along the horizontal sections. It may also be preferred to apply corrugations and/or weakened regions only along the vertical sections. In further preferred embodiments, corrugations and/or weakened regions are applied to the vertical sections and the horizontal sections. Furthermore, it may be preferred that corrugations and/or weakened regions at connection points are present alone or in combination with further corrugations and/or weakened regions at vertical and/or horizontal sections.

Advantageously, corrugations and/or weakened regions on horizontal sections and at connection points lead to an increase in the freedom of rotation of the vertical sections. Corrugations and/or weakened regions on vertical sections advantageously reduce the bending rigidity such that the displacement of the vertical sections can be further increased. Both positionings can be used alone or in combination to generate high sound pressure levels without significant distortions occurring.

In a further preferred embodiment, the MEMS transducer is characterized in that at least 1, 2, 3, 4, 5 or more corrugations and/or weakened regions are provided along a vertical section and/or a horizontal section.

Advantageously, the number of corrugations and/or weakened regions is a parameter that can be selected to optimize the vibration behavior of the vertical sections. A higher number of corrugations and/or weakened regions on vertical sections and/or joints advantageously results in greater freedom of rotation. A higher number of corrugations and/or weakened regions on the vertical sections advantageously results in greater displacement of the vertical sections by reducing the rigidity of the vertical sections to a greater extent.

In further applications, it may be preferable to provide a relatively small number of corrugations and/or weakened regions, for example only one or two corrugations and/or weakened regions per vertical and/or horizontal section. Consequently, the vibration behavior of the vibratable membrane can advantageously be optimized in a particularly simple manner by a corresponding selection, in particular with regard to the number of corrugations and/or weakened regions.

In a further preferred embodiment, the MEMS transducer is characterized in that the one or more corrugations exhibit a rectangular, trapezoidal, square, triangular, semi-circular and/or round cross-section.

The aforementioned geometric shapes can advantageously promote the optimization of the vibration behavior via the corrugations. In addition, the production of these geometric shapes of the corrugations has advantageously proven to be particularly simple. The preferred cross-sections of the corrugations can be made possible, for example, by providing a correspondingly shaped shaping component or a structured carrier substrate and a subsequent coating process.

Preferably, one or more corrugations exhibit a rectangular cross-section. A rectangular cross-section is preferably characterized by a flat quadrilateral whose internal angles are all essentially right angles. It may also be preferred that one or more corrugations exhibit a trapezoidal cross-section. A trapezoidal cross-section is preferably characterized by a flat quadrilateral with two sides that are substantially parallel to each other. Furthermore, it may be preferred that one or more corrugations exhibit a square cross-section. A square cross-section is preferably characterized by four sides of substantially equal length and four substantially right angles. It may also be preferred that one or more corrugations exhibit a triangular cross-section. A triangular cross-section is preferably characterized by three angles that are spanned by their sides.

It may also be preferable for one or more corrugations to exhibit a partially circular cross-section. Here, “partially circular” preferably refers to a partial section of a circular shape. A partially circular cross-section can preferably also be in the form of a substantially semi-circle. In addition, it may be preferred that a round cross-section of one or more corrugations is present. A round cross-section preferably means a cross-section that does not have corners and/or edges within the corrugations and can, for example, be semi-circular or exhibit a different shape (elliptical, etc.).

In a preferred embodiment, the MEMS transducer is characterized in that the one or more corrugations exhibit a depth of 1 μm-100 μm, preferably 2 μm-20 μm, and/or a width between approx. 0.5 μm-50 μm, preferably between 1 μm-5 μm.

In a further preferred embodiment, the MEMS transducer is characterized in that the one or more corrugations exhibits an aspect ratio of width to depth of 1:1 or more, preferably 1:2 or more. The aspect ratio is preferably defined as the ratio of the depth or height to the (smallest) lateral dimension.

The aforementioned aspect ratios are advantageous in that they entail a particularly effective increase in the displacement of the vertical sections and can also be produced simply and reliably using methods known in the prior art.

In a preferred embodiment, the MEMS transducer is characterized in that the horizontal sections and/or vertical sections are formed in a plurality of layers and wherein one or more weakened regions are achieved by variation of the layer thickness of at least one layer, wherein preferably the layer thickness of the at least one layer is reduced to less than 70%, preferably less than 60%, 50%, 40% or less of an initial layer thickness.

As described above, a weakened region preferably means a reduced layer thickness of a layer of the membrane compared to the average thickness of the partial section of the membrane. In the case of a multilayer membrane, the variation of the layer thicknesses in the weakened region can relate to a reduction in the layer thickness of a selection of the layers, for example one or two layers or all layers of the multilayer membrane. Weakened regions exhibit similar advantageous technical effects as the application of corrugations.

The aforementioned reductions in layer thicknesses have proven to be advantageous in that they are particularly easy and quick to provide and also enable particularly efficient optimization of the vibrational behavior of the vibratable membrane.

In a further preferred embodiment, the MEMS transducer is characterized in that the horizontal sections and/or vertical sections are formed in a plurality of layers and wherein one or more weakened regions are formed by reducing a layer thickness of at least one layer to 0% in certain regions. Preferably, this may concern a layer comprising a conductive material, a layer comprising a support material and/or the actuator layer. In embodiments, it may be preferred that one or more weakened regions are provided by reducing a layer thickness of all layers of the membrane to 0% of an initial layer thickness, provided that these layers comprise an actuator material, a mechanical support material or a conductive material. In these embodiments, however, it may be preferred that the formation of continuous openings is avoided by providing a cover layer, preferably a layer of a polymeric material, which extends at least over the weakened regions. Preferred embodiments of the cover layer, preferably in the form of a polymer layer, are disclosed elsewhere herein.

A reduction to 0% of the initial layer thickness preferably denotes the complete absence of a layer in at least one partial region of the membrane, which therefore defines the weakened region, such that in the context of the invention this can also be referred to synonymously as an absence or a recess of a layer in the relevant (weakened) region.

With a weakened region, which is characterized by the absence of a layer in certain areas, for example, a reduced actuation can be achieved.

For example, there may be a recess in a conductive material of the membrane—such as a top and/or bottom electrode.

Preferably, a top electrode can be omitted in one or more weakened regions, for example in a horizontal section. In the region in which the top electrode is omitted, no or only a reduced electric field may be formed between the top and bottom electrodes, in contrast to the remaining horizontal section of the membrane. A piezoelectric actuator layer, which is located between the top and bottom electrodes, is therefore not induced or actuated to change shape, or is induced or actuated to change shape to a lesser extent, in the region of the top electrode recess. Similarly, it may be preferred for one weakened region or a plurality of weakened regions to be formed by recessing a bottom electrode in certain areas.

The reduced or weaker actuation is based—without being limited to theory—on a weakened electric field. The reduced actuation is therefore preferably the result of a reduction or elimination of a piezoelectric effect at the relevant point. This can advantageously optimize the vibrational behavior of the membrane by increasing the movability of adjacent vertical sections and/or avoiding undesirable effects such as buckling.

Such a reduction in the actuation capacity of the membrane in certain areas can also be caused by the absence of an actuator layer in certain areas—for example a piezoelectric actuator layer.

It may also be preferable for the actuator layer to be replaced by a material that is not an actuator material, for example a dielectric material, in the section of the weakened region. Advantageously, by replacing a functional layer (e.g. an actuator layer) with a non-functional layer (e.g. a dielectric material as an insulating material) in certain regions, the effect of reduced actuation can be achieved while maintaining a homogeneous overall layer thickness in the weakened region.

Furthermore, it may also be preferred to additionally introduce an insulating material as an insulating layer (e.g. a dielectric material) in a weakened region—for example between a layer comprising a conductive material (top and/or bottom electrode)—and the actuator layer. This also reduces the piezoelectric effect and thus the actuation capacity of the multilayer membrane in the weakened region. In this case, this may preferably be a weakened region due to a variation of the layer thickness of at least one layer, in which an additional layer is introduced and the overall thickness of the membrane may even increase.

In further preferred embodiments, a weakened region can also be characterized by the absence or omission of a mechanical support layer in some regions. This reduces the rigidity of the relevant partial region, such that the displacement of the membrane can also be optimized. It is also understood that in the case of the mechanical support layer, the omitted support material can also be replaced by a material with lower mechanical rigidity (or a higher modulus of elasticity).

The recess of one or more layers may be formed during the coating process by a predetermined masking. It may also be preferable to provide the recess after coating by means of structuring.

In preferred embodiments, a weakened region, which is characterized by the absence of at least one layer, is present at a horizontal section. It may also be preferred that such an area of weakness is located within a corrugation. This means, for example, that at least one layer (e.g. a support layer, actuator layer, top and/or bottom electrode) is omitted in a corrugation, which is characterized as a depression or elevation in an otherwise essentially planar course of the partial section.

In particularly preferred embodiments, the MEMS transducer is characterized in that the horizontal sections and/or vertical sections are formed in a plurality of layers and wherein one or more weakened regions are achieved by a variation of the layer thickness of at least one layer (preferably exactly one layer), wherein preferably the layer thickness of the at least one layer is reduced to less than 70%, preferably less than 60%, 50%, 40% or to 0% of an initial layer thickness, but wherein the layer thickness of at least one layer of the membrane (preferably all layers except one layer) is not reduced. This specifically changes the mechanical or functional properties of the membrane in the weakened region without impairing the integrity of the membrane. Any acoustic disadvantages due to the provision of continuous openings can therefore be avoided. The preferred layer, which remains in place, can for example be an actuator layer, a mechanical support layer or a layer comprising a conductive material. It may also be preferred that only a cover layer remains, preferably comprising a polymer material. The cover layer preferably substantially exhibits the function of avoiding a complete continuous opening of the membrane in the weakened regions, the cover layer preferably being non-conductive and/or not permeable to a fluid in which the sound waves propagate, preferably air.

In some embodiments, however, the weakened regions can also be provided as continuous openings, wherein the layer thickness of all layers is reduced to 0% in some regions. The mechanical rigidity of the horizontal sections and/or vertical sections can also be reduced by providing continuous openings, resulting in improved vibrational behavior of the membrane.

This can be optimized in particular by the geometric shape of the openings and/or the number of openings. In preferred embodiments, there are 1, 2, 3, 4, 5, 6, 7, 8, 9, 10, 15, 10, 30, 50, 100 or more openings on a horizontal and/or vertical section. The more openings there are, the greater the mechanical resistance can be reduced during vibration. The openings can preferably be circular, elliptical, angular or applied as a slot. In a further preferred embodiment, the MEMS transducer is characterized in that a rigidity of the horizontal sections and/or vertical sections can be adjusted by configuring one or more corrugations and/or weakened regions, preferably with regard to depth, width, layer thickness, geometry and/or number, in order to optimize the vibrational behavior of the vertical sections.

Advantageously, a rigidity of the vertical sections can thus be optimized by a configuration and/or selection of parameters comprising depth, width, layer thickness, geometry and/or number, in particular adapted depending on the application purpose of the MEMS transducer. In particular, the rigidity of the vertical sections includes the bending rigidity, i.e. the resistance to bending during horizontal vibration, for example to generate or receive pressure waves. By reducing the bending rigidity, a higher maximum displacement of the vertical sections is advantageously given, so that advantageously also higher sound pressure levels with good sound quality can be generated by a preferred MEMS loudspeaker. With regard to a preferred provision of the MEMS transducer as a MEMS microphone, its sensitivity, recording quality and/or signal-to-noise ratio can advantageously be improved.

In preferred embodiments, the membrane comprises a cover layer, preferably in the form of a polymer layer. A polymer layer preferably characterizes a layer of a polymer material and is particularly preferred in those embodiments in which the other functional layers of the membrane, such as the layers of an actuator material, an electrically conductive material and/or a mechanical support material, are omitted.

In this embodiment, it is therefore preferred that in a weakened region the layer thickness of all layers of the membrane are reduced to 0% of an initial layer thickness, except for the layer thickness of a cover layer, which is preferably a layer comprising a polymer material.

The provision of a cover layer in these embodiments is advantageous in that an acoustic short circuit is reliably avoided regardless of the size of the recesses or openings to be provided. In the case of continuous openings in the membrane with dimensions of approx. 5 μm or more, an acoustic short circuit can occur. An acoustic short circuit preferably means a reduction in sound radiation in the case of a loudspeaker or a reduction in sound reception in the case of a microphone due to an undesirable pressure equalization between a rear and a front side of the membrane. An acoustic short circuit can occur in particular when sound is emitted or received in the low-frequency range. Such pressure equalization can be avoided for frequencies of desired applications by selecting smaller dimensions of continuous openings.

Advantageously, the use of a cover layer, for example a polymer layer, prevents the occurrence of an acoustic short circuit also for openings or recess of any preferred size. This advantageously increases the design flexibility with regard to the provision of weakened regions as recesses in the layers comprising an actuator material, a support material or an electrically conductive material.

In preferred embodiments, the cover layer can be located on a front side or on a rear side of the membrane. A front side preferably means the side of the membrane into which sound is emitted or from which sound waves are detected.

In preferred embodiments, the cover layer extends substantially continuously over the entire surface of the membrane. This means in particular that the top layer is substantially identical in design and dimensions to the layers of the membrane below or above it. It is therefore preferred that the cover layer is present as a single, preferably continuous, layer on the membrane.

In further preferred embodiments, it may be preferred that the cover layer, preferably in the form of a polymer layer, is only present at least at the weakened regions where the prevention of an acoustic short circuit is desired and is not present in other areas of the membrane where there are no weakened regions. Consequently, it may be preferred that the cover layer does not extend completely along the membrane, but is selectively applied to cover the weakened regions or openings. In this embodiment, an interrupted, discontinuous cover layer may thus preferably be present, although the cover layer is provided at least at the weakened regions of the membrane.

In preferred embodiments, the cover layer is provided as a polymer film, polymer liquid or polymer varnish. Preferably, the cover layer is not permeable to a fluid in which the sound waves propagate, for example air. Preferably, the cover layer is therefore impermeable to gas in order to maintain the acoustic integrity of the membrane and avoid an acoustic short circuit. It is also preferred that the cover layer is not electrically conductive. In particular, it is preferred that the cover layer comprises a dielectric material. For example, it may be preferred that the cover layer comprises a polymeric material selected from a group comprising polyvinyl difluoride (PVDF), polymethyl methacrylate (PMMA), parylene and/or SU-8 polymide.

In preferred embodiments, the top layer exhibits a layer thickness of between 5-100 nm, preferably between 10-80 nm, particularly preferably between 20-60 nm, most preferably between 30-50 nm.

In a preferred embodiment, the MEMS transducer is characterized in that the introduction of one or more corrugations and/or weakened regions at the horizontal sections and/or vertical sections increases a rotational freedom of the vertical sections in order to optimize a vibrational behavior of the vertical sections.

Advantageously, by increasing the freedom of rotation, the movability can be increased starting from the connection point of the vertical sections on the horizontal sections. The increase in rotational freedom can therefore preferably be understood as improved movability at the fixing point on the horizontal section.

In a preferred embodiment, the vibratable membrane is configured as a meander structure, with the meander structure being formed by the vertical sections and horizontal sections.

A meander structure preferably refers to a structure formed from a sequence of sections that are essentially orthogonal to each other in cross-section. The mutually orthogonal sections are preferably vertical and horizontal sections of the vibratable membrane. It is particularly preferred that the meander structure is rectangular in cross-section. However, it may also be preferred that the meander structure exhibits a sawtooth shape (zig-zag shape) in cross-section or is curved or wavy. This is particularly the case if the vertical sections are not aligned exactly parallel to the vertical emission or detection direction, but include an angle of ±30°, preferably ±20°, particularly preferably ±10° with the vertical direction. Preferably, the meander structure comprises structural and/or functional irregularities or inhomogeneities in the form of corrugations and/or weakened regions.

In preferred embodiments, the horizontal sections may also not be at an exact orthogonal angle of 90° to the vertical emission or detection direction, but may, for example, include an angle between 60° and 120°, preferably between 70° and 110°, particularly preferably between 80° and 100° with the vertical direction.

In the case of a curved shape of the vertical and/or horizontal sections of the vibratable membrane in cross-section, the alignment preferably refers to a tangent to the vertical and/or horizontal sections at their respective centers.

In this case too, the corrugations according to the invention preferably define a local deviation (depression or elevation) from an otherwise continuous course of the (curved) vertical and/or horizontal sections.

The meander structure thus preferably corresponds to a membrane folded along its width. For the purposes of the invention, a vibratable membrane can therefore preferably also be referred to as a bellows. The parallel folds of the bellows preferably form the vertical sections. The connecting sections between the folds preferably form the horizontal sections. Preferably, the vertical sections are longer than the horizontal sections, for example by a factor of 1.5, 2, 3, 4 or more.

With regard to the function of a vibratable membrane in meander form for generating or absorbing sound waves, the vertical sections, which can also be referred to as lamellae, are decisive. Preferably, the vertical sections are multi-layered and form a mechanical bimorph. For example, the vertical sections can each comprise an actuator layer and a passive layer consisting of a support material and/or two differently drivable actuator layers. The horizontal sections of the folded membrane can preferably be constructed identically to the vertical sections. However, it may also be preferred that the horizontal sections—in contrast to the vertical sections—do not exhibit an actuator layer, but only a mechanical support layer and/or an electrically conductive layer.

In a preferred embodiment, the at least one layer of actuator material of the vibratable membrane is a continuous layer. Continuous preferably means that there are no interruptions in the cross-sectional profile. Accordingly, in the embodiment mentioned, it is preferred that there is a continuous layer of actuator material in both the vertical and horizontal sections. Advantageously, therefore, no structuring is necessary. A continuous layer is particularly easy to produce and ensures synchronous actuation during operation of a MEMS loudspeaker. With regard to the formation of weakened regions, however, it may also be preferred to introduce specific interruptions or recesses in an actuator layer in order to optimize the vibrational behavior.

The performance of the MEMS transducer, in particular a MEMS loudspeaker or MEMS microphone, can be significantly determined by the number and/or dimensions of the vertical sections, wherein in particular corrugations and/or weakened regions, as explained above, entail a particularly defined curvature and displacement of the vertical regions.

In preferred embodiments, the vibratable membrane comprises more than 3, 4, 5, 10, 15, 20, 30, 40, 50, 100 or more vertical sections.

In preferred embodiments, the vibratable membrane comprises less than 10,000, 5,000, 2,000 or 1,000 or fewer vertical sections.

The preferred number of vertical sections entails a high sound power on the smallest chip surfaces, whereby an excellent sound image and outstanding audio quality is achieved in particular by providing the corrugations and/or weakened regions.

Preferably, the vertical and/or horizontal sections are substantially planar, which means in particular that their extension in each of the two dimensions (height, width) of their surface area is greater than in a dimension perpendicular to this (the thickness). For example, size ratios of at least 2:1, preferably at least 5:1, 10:1 or more may be preferred. Corrugations and/or weakened regions preferably define deviations from a flat plane, as explained above.

For the purposes of the invention, the height of the vertical sections preferably corresponds to the dimension along the direction of sound emission or sound detection. In relation to the horizontal sections, on the other hand, a width preferably denotes the dimension along the connecting line between two vertical sections.

A thickness of the vertical and/or horizontal sections preferably corresponds to a sum of the layer thickness of the one or more layers forming the vertical and/or horizontal sections. The length of the vertical and/or horizontal sections preferably corresponds to a dimension orthogonal to the height or width and to the thickness. In the cross-sectional views of the figures below, the height or width and thickness are shown schematically (not necessarily true to scale), while the length dimension corresponds to a (non-visible) drawing depth of the figures.

In a preferred embodiment, a height of the vertical sections is between 10 μm and 1 000 μm, preferably between 50 μm and 500 μm, while a width of the horizontal sections is between 2 μm and 200 μm, preferably between 5 μm and 100 μm.

In a preferred embodiment, a thickness of the vertical and/or horizontal sections is between 100 nm and 10 μm, preferably between 500 nm and 5 μm and/or a length of the vertical and/or horizontal sections is between 10 μm and 10 mm, preferably between 100 μm and 1 mm.

In preferred embodiments, the corrugations or weakened regions exhibit a constant cross-section or layer thickness variation in the length dimension and can therefore also be referred to as grooves or webs.

In the case of a recess in layers made of a conductive material, i.e. preferably the top and/or bottom electrode, it is preferred that the weakened regions do not represent continuous interruptions in the length dimension of the planar membrane. Instead, it may be preferable, for example, to provide conductive tracks or remaining conductive areas which ensure contact at the ends and continuous current flow in the top and/or bottom electrode. Thus, the recess of the top and/or bottom electrode may preferably be present substantially along the entire length dimension of the membrane, the recess being interrupted by thin (e.g. less than 20 μm, preferably less than 10 μm) conductive regions or conductive tracks.

With the aforementioned preferred dimensions of the vibratable membrane or the vertical sections, a particularly compact MEMS transducer, in particular a MEMS loudspeaker or MEMS microphone, can be provided, which simultaneously combines high performance with excellent sound image or audio quality.

In a further aspect, the invention relates to a production method for a MEMS transducer, preferably a MEMS loudspeaker or MEMS microphone, comprising the following steps:
Etching a substrate, preferably from a front side, to form a structure, preferably a meander structure, and preferably to form corrugations,
Optional application of an etch stop,
Application of at least two layers, wherein at least a first layer comprises an actuator material and a second layer comprises a mechanical support material or at least two layers comprise an actuator material, wherein preferably one or more weakened regions are provided in the process of applying the at least two layers or by subsequent etching.
Contact of the first and/or second layer with an electrode,
Etching of the substrate, preferably from the rear side, and optional removal of the etch stop, such that the vibratable membrane is fixed to the carrier for effecting vibrations, wherein the vibratable membrane exhibits vertical sections and horizontal sections, wherein the vertical sections are formed substantially parallel to the vertical direction and the horizontal sections connect the vertical sections to each other, wherein the vertical sections and/or the horizontal sections exhibit one or more corrugations and/or weakened regions,
such that the vertical sections can be induced to vibrate horizontally by driving the electrode or an electrical signal can be generated at the electrode when the vertical sections are induced to vibrate horizontally.

The average person skilled in the art will recognize that technical features, definitions and advantages of preferred embodiments of the described MEMS transducer, preferably MEMS loudspeaker or MEMS microphone, also apply to the described production method and vice versa. Preferably, the described production method serves to provide a MEMS transducer with a folded vibratable membrane with a meander structure. Examples of preferred manufacturing steps are shown in FIG. 2 a-h.

Preferably, etching the substrate comprises applying a structure congruent to the meander structure for the membrane, in order to provide vertical and horizontal sections as well as corrugations and/or weakened regions after coating. Alternatively, corrugations and/or weakened regions may be provided by structuring or coating by means of masking. It may also be preferable to provide weakened regions, for example in the form of recesses in at least one layer, by subsequent structuring (etching) of the membrane.

For example, one of the preferred materials mentioned above can be used as a substrate. During etching, a blank, for example a wafer, can be formed into the desired basic shape of the meander structure. In the next step, the layers for the vibratable membrane are preferably applied.

The application of at least one layer of a conductive material preferably comprises not only the application of one layer but also the application of a plurality of layers and, in particular, a layer system. A layer system comprises at least two layers applied to each other in a planned manner. The application of a layer or a layer system preferably serves to define the vibratable membrane comprising vertical sections which can be induced to vibrate horizontally.

In preferred embodiments, after an optional application of an etch stop, a cover layer can be coated in the form of a polymer layer. It may then be preferred to apply the other preferred layers for the membrane and to structure them accordingly in order to provide corrugations and/or weakened regions, in particular openings. A membrane is then present which has a cover layer, preferably in the form of a polymer layer, as the bottom layer.

It may also be preferred to apply the cover layer as the last layer, i.e. as the uppermost layer in the context of a coating. Preferably, the cover layer is applied in the form of a polymer layer as the last layer after a structuring of layers in order to apply corrugations and/or weakened regions, in particular openings, to the membrane. This results in a membrane with a polymer layer as the uppermost layer.

As explained above, the use of a cover layer, in particular in the form of a polymer layer, has proven to be particularly advantageous for avoiding acoustic short circuits. This is particularly the case if it is preferable to omit all other layers of a membrane (e.g. actuator layer, mechanical support layer and/or layer comprising a conductive material) in the relevant weakened regions.

Preferably, the deposition can be selected from the group comprising physical vapor deposition (PVD), in particular thermal evaporation, laser beam evaporation, arc evaporation, molecular beam epitaxy, sputtering, chemical vapor deposition (CVD) and/or atomic layer deposition (ALD).

Etching and/or structuring can preferably be selected from the group comprising dry etching, wet chemical etching and/or plasma etching, in particular reactive ion etching, reactive ion deep etching (Bosch process).

If further structuring of the vibratable membrane is desired—for example to form weakened regions as described—this can be achieved by further etching processes, for example. Additional material can also be deposited or doping can be carried out using conventional processes.

Suitable material, such as copper, gold and/or platinum, can also be deposited using conventional processes for making contact with the layers. Physical vapor deposition (PVD), chemical vapor deposition (CVD) or electrochemical deposition can be used for this purpose.

By means of the method steps, a finely structured vibratable membrane with a desired definition of vertical and horizontal sections can be provided, which is preferably suspended between two lateral regions of a stable carrier and has dimensions in the micrometer range. The production steps are standard process steps of semiconductor processing, such that they have been tried and tested and are also suitable for mass production.

The invention will be explained below with reference to further figures and examples. The figures and examples serve to illustrate preferred embodiments of the invention without limiting it.

### FIGURES

### Brief Description of the Figures

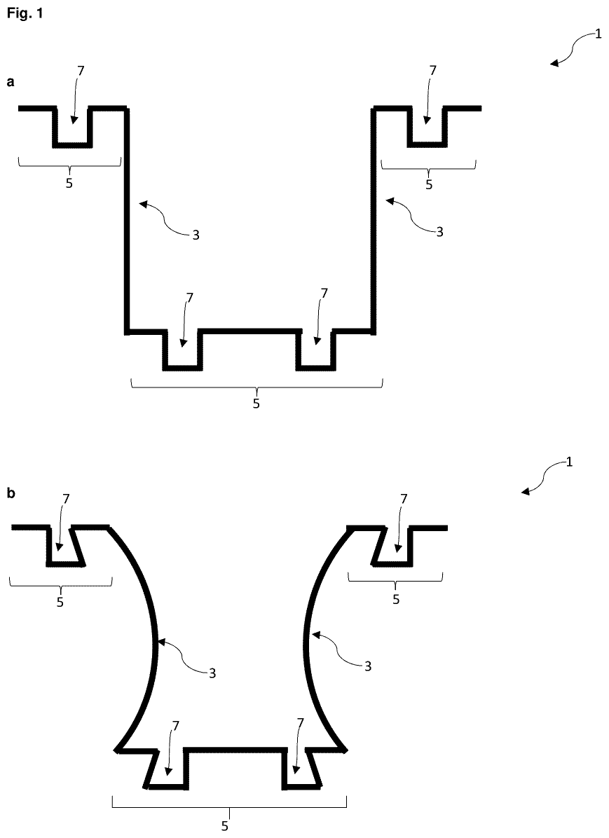

FIG. 1 Schematic representation of corrugations on vertical and horizontal sections

FIG. 2 Schematic representation of preferred method steps for producing a MEMS transducer

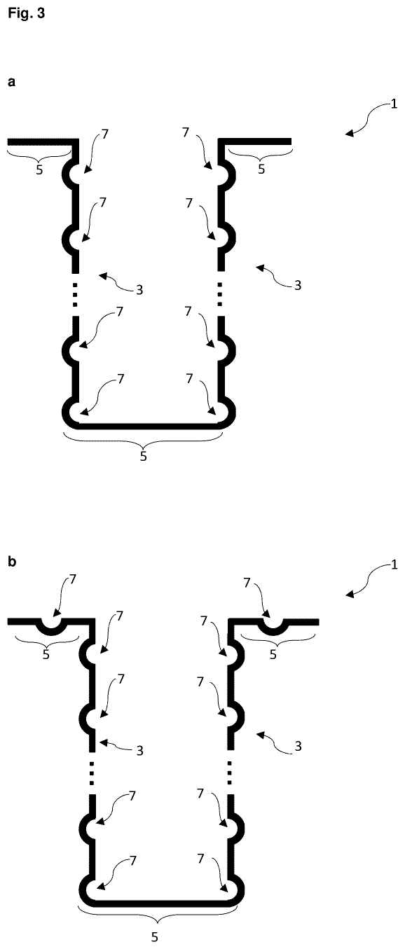

FIG. 3 Schematic representation of corrugations on vertical and horizontal sections

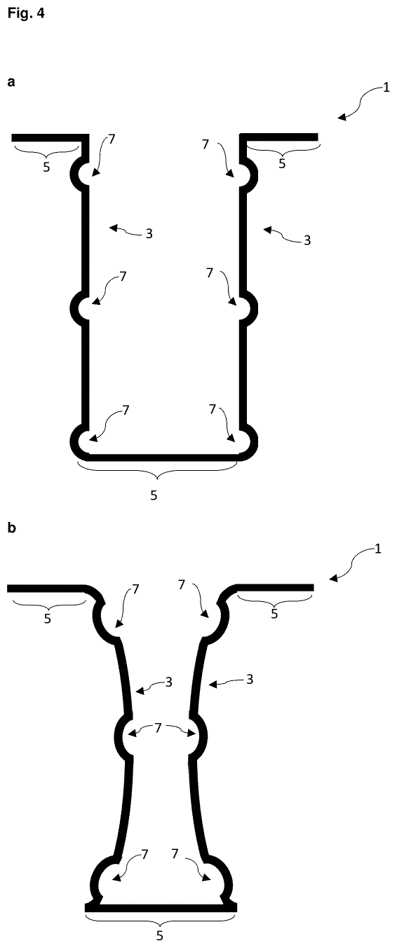

FIG. 4 Further schematic representation of corrugations on vertical sections

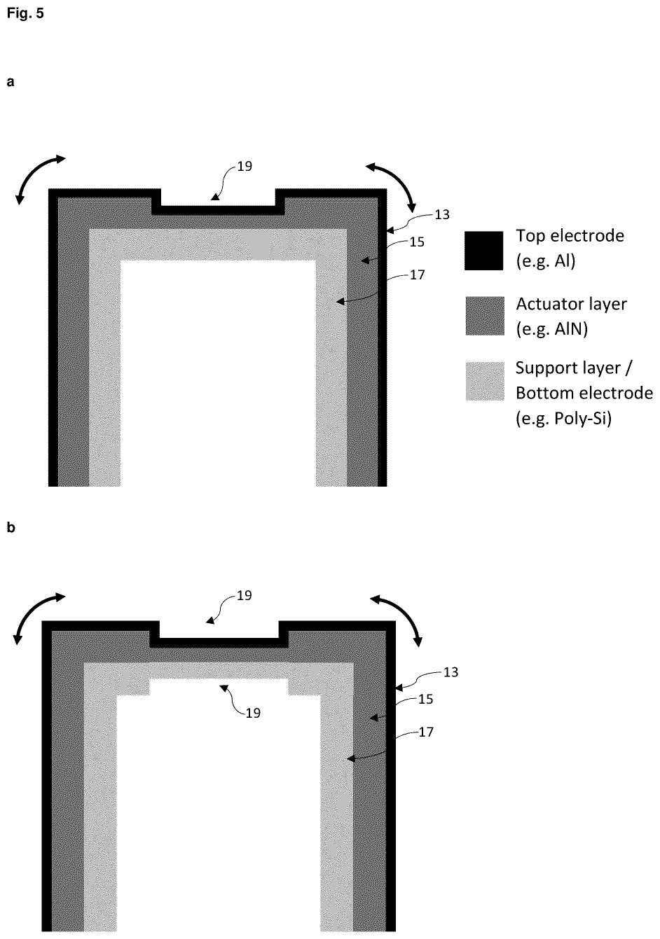

FIG. 5 Schematic representation of weakened regions on horizontal sections

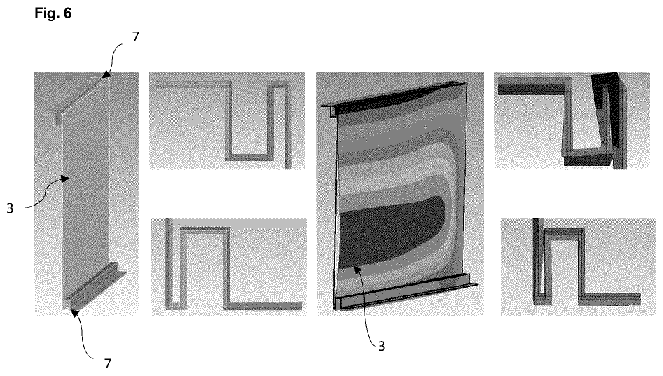

FIG. 6 Simulation results for the vibrational behavior of a vertical section in the event of the introduction of corrugations in adjacent horizontal sections

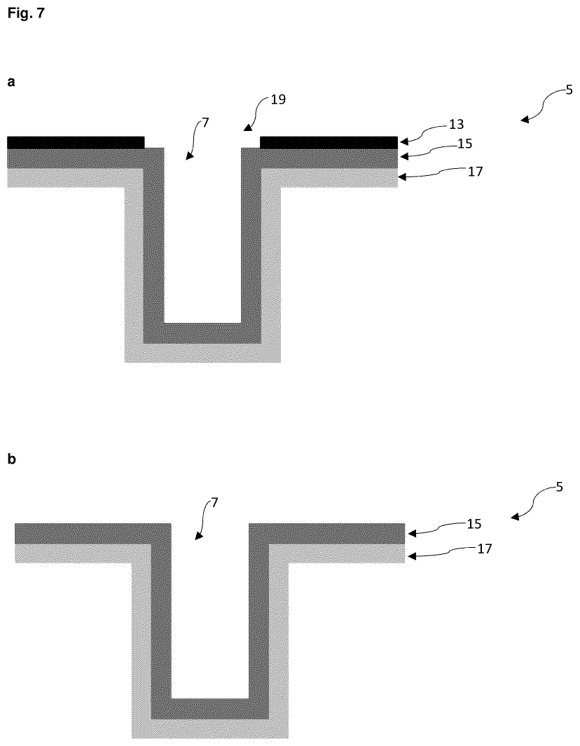

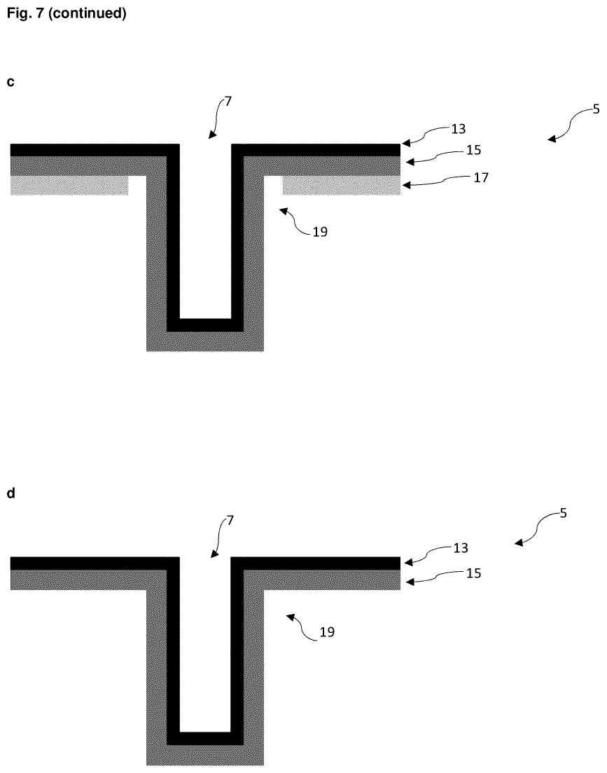

FIG. 7 Schematic representation of weakened regions resulting from the provision of recesses in the top or bottom electrode

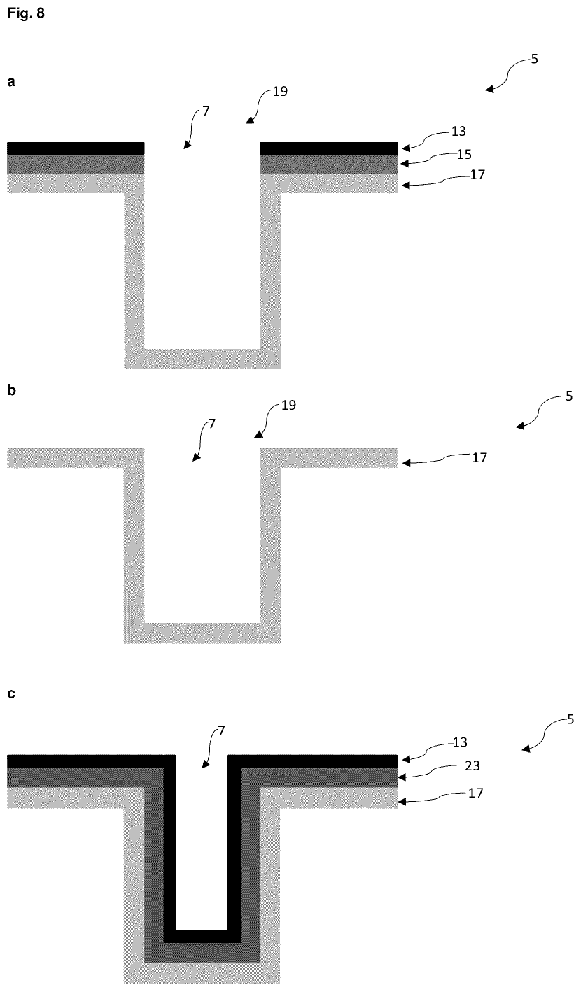

FIG. 8 Schematic representation of weakened regions resulting from structuring of the actuator layer

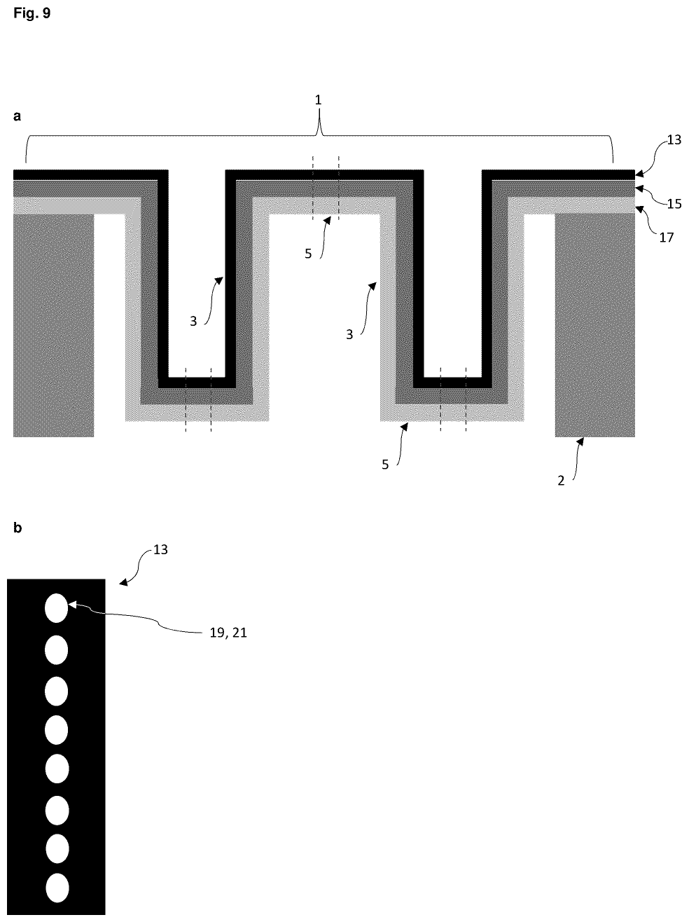

FIG. 9 Schematic representation of weakened regions resulting from the formation of continuous openings

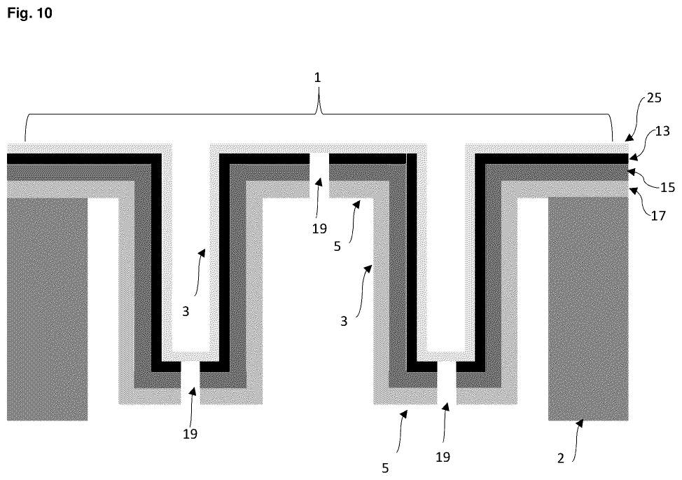

FIG. 10 Schematic representation of a preferred embodiment of a MEMS transducer comprising a top layer in the form of a polymer layer

### DETAILED DESCRIPTION OF THE FIGURES

FIG. 1 a, b illustrates a vibratable membrane 1 of a MEMS transducer, which exhibits corrugations 7 on its vertical sections 3 and horizontal sections 5.

FIG. 1a shows a rectangular cross-section of the corrugations 7, while FIG. 1b illustrates a trapezoidal cross-section.

Advantageously, the vibration behavior of the vibratable membrane 1 can be optimized by configuring the geometric shape of one or more corrugations 7.

On the one hand, the corrugations 7 entail a higher degree of rotation of the vertical sections 3, which ensures a particularly efficient displacement capacity of the vibratable membrane. On the other hand, the corrugations have the advantage that the vertical sections undergo a particularly defined curvature when pressure waves are generated or received (see FIG. 1b). The potential occurrence of irregular buckling is prevented particularly effectively.

Furthermore, the targeted introduction of corrugations 7 allows higher amplitudes of the horizontal vibrations.

In the case of a MEMS loudspeaker, for example, this results in a higher displacement of the fluid volume between the vertical sections 3, which enables an increase in the generated sound pressure level. Accordingly, in the case of a MEMS microphone, more fluid volume can be received between the vertical sections and the sensitivity of the sound detector can be increased. The particularly uniform curvature of the vertical sections 7 during the horizontal vibrations also reduces the occurrence of harmonic distortions. This results in a particularly good sound quality both when receiving and when generating pressure waves of a fluid.

FIG. 2 shows preferred method steps for producing an embodiment of a MEMS transducer according to the invention.

FIG. 2 a illustrates a substrate 9 that was previously etched from a front side to form a structure. In the etching process, on the one hand, parallel deep trenches (pockets) were formed in the substrate 9 such that the formed structure represents a bellows or a meander in cross-section. On the other hand, the etching process provided elevations or depressions in sections of the substrate 9, which will form the horizontal sections, to form the corrugation.

FIG. 2 b illustrates the application of an etch stop 11, which acts as a sacrificial layer and is intended to protect the vertical sections 3 and/or the horizontal sections 5 during rearside etching to expose the membrane.

A layer of mechanical support material 17 is applied to the etch stop 9 (FIG. 2 c). The mechanical support material 17 can preferably also be a conductive material, e.g. polysilicon, such that the layer of mechanical support material 17 can also act as a bottom electrode.

In FIG. 2 d, a middle layer comprising an actuator material 15 is coated on the layer of a mechanical support material 17. The actuator material 15 can preferably be a piezoelectric material, e.g. AlN.

Subsequently, FIG. 2 e shows that an upper layer comprising a conductive material 13 is coated, wherein the upper layer 13 will act as a top electrode.

FIG. 2 f shows the application of an electrode pad for making contact with the upper layer of a conductive material 13, which acts as the top electrode, and the lower layer of a conductive, mechanical support material 17, which acts as the bottom electrode.

In FIG. 2 g, the substrate 9 is etched from a rear side to expose the vibratable membrane 1 and form a carrier 2. The carrier 2 comprises two lateral regions, between which the vibratable membrane 1 is arranged in a horizontal direction. The vibratable membrane 1 is formed as a meander structure, wherein the meander structure is formed by the vertical sections 3 and horizontal sections 5. After etching the substrate, the horizontal sections 5 now exhibit corrugations 7 according to the invention, which entail a significant improvement in the vibrational behavior of the vibratable membrane 1.

The arrows shown in FIG. 2 h serve to illustrate the horizontal vibrations of the vertical sections 3. In particular, the freedom of rotation of the vertical sections 3 is increased by attaching corrugations 7, such that the vibrational behavior of the vibratable membrane 1 can be optimized.

FIG. 3 shows another preferred embodiment of a vibratable membrane 1 comprising corrugations 7. The corrugations 7 shown exhibit a round, semi-circular cross-section.

In FIG. 3 a, the corrugations 7 are applied to the vertical sections 3. By applying corrugations 7 to the vertical sections 3, the bending rigidity is advantageously reduced such that a higher displacement capacity of the vertical sections 3 can be achieved.

FIG. 3 b shows the vibratable membrane 1 from FIG. 3 a. However, corrugations 7 are now also applied to the horizontal sections 5, having a further advantageous effect on the freedom of rotation of the vertical sections 3.

FIG. 4 shows a schematic representation of corrugations 7 on vertical sections 3 and now also at the connection points between horizontal sections 5 and vertical sections 3.

While FIG. 4 a shows an initial position of the vertical sections 3, FIG. 4 b shows a displacement of the vertical sections 3, e.g. by driving an electrode. The corrugations 7 ensure a uniform curvature without the risk of irregular buckling occurring.

FIG. 5 shows a preferred embodiment for forming weakened regions 19 on horizontal sections 5.

In the preferred embodiment, the membrane 1 is made up of a plurality of layers. A bottom layer of mechanical support material 17 is formed from a conductive material (here: polysilicon), such that the bottom layer of mechanical support material 17 simultaneously functions both as a bottom electrode and as a carrier layer. A middle layer comprising an actuator material 15 (here: aluminum nitride AlN as a piezoelectric layer) and an upper layer comprising conductive material 13 (here: aluminum), which acts as a top electrode, are present on the layer of support material 17.

In FIG. 5 a, the layer thickness of the middle actuator layer 15 is reduced in some areas compared to the initial layer thickness to form a weakened region 19.

In FIG. 5 b, in addition to varying the layer thickness of the middle actuator layer 15, the layer thickness of the lower support layer 17 is reduced in some areas compared to the initial layer thickness to form a weakened region 19.

Advantageously, similar effects in terms of optimizing the vibrational behavior of the vertical sections 3 can be achieved by weakened regions 19 as by applying corrugations.

In particular, the introduction of weakened regions 19 allows a reduction in the rigidity of horizontal sections 5, such that the displacement of the vertical sections 3 is increased. The arrows in FIG. 5 a and b illustrate the resulting improved freedom of movement and rotation of the vertical sections 3.

FIG. 6 shows the results of a simulation of the vibrational behavior of a vertical section 3 when corrugations 7 are applied to adjacent horizontal sections.

As can be seen in FIG. 6, the freedom of rotation of the vertical sections 3 can be increased by applying corrugations 7 to horizontal sections 5, resulting in a particularly uniform curvature of the vertical sections 3 without irregular buckling occurring.

FIG. 7 shows a schematic representation for a preferred provision of weakened regions 19 by providing recesses in the top or bottom electrode. The weakened regions 19 are thus characterized by a reduction of a layer thickness of the layer of a conductive material 13 (top or bottom electrode) to 0% in some regions.

FIG. 7 a shows a section of a horizontal section 5 with a corrugation 7. The membrane 1 comprises an upper layer of a conductive material 13, which acts as a top electrode, an actuator layer 15 comprising an actuator material and a lower layer of a conductive material 13, which also acts as a support layer 17 and bottom electrode. The weakened region 19 is present in such a way that the conductive material 13 or the top electrode is omitted over the area of the corrugation 7. In the area where the top electrode is omitted, there may be no or only a reduced electric field between the top and bottom electrodes, in contrast to the remaining horizontal section 5 of the membrane. The actuator layer 15, preferably comprising a piezoelectric material, which is present between the top and bottom electrodes, is therefore not induced or actuated, or is induced or actuated to a lesser extent, to change shape in the area of the recess of the top electrode.

The reduced actuation therefore results from a local reduction in the piezoelectric effect at the point in question. This has the advantage of optimizing the vibrational behavior of the membrane by increasing the movability of adjacent vertical sections and/or avoiding undesirable effects such as buckling.

FIG. 7 b shows a section of a membrane with a corrugation 7 along a horizontal section 5. The membrane comprises an actuator layer 15 comprising an actuator material, which is applied to a layer of conductive material 13, which also acts as a support layer 17. This provides a weakened region 19 such that the conductive material 13 or the top electrode is omitted not only in the area of the corrugation 7, but also in other areas of the horizontal section 5.

FIGS. 7 c and 7 d show analogous embodiments to FIGS. 7 a and b, but the weakened region 19 is formed by recesses in the lower layer of conductive material 13, which acts both as a bottom electrode and as a support layer 17. The weakened region 19 is therefore present in such a way that the conductive material 13 or the bottom electrode is omitted over the area of the corrugation 7. In addition to the effect of reduced actuation of the actuator layer 15, the absence of the support layer 17 contributes to a reduction in the rigidity of the membrane 1 in this region and allows the vibrational behavior to be optimized.

In FIG. 7 c, the weakened region 19 is present such that the conductive material 13 or the top electrode is omitted in the area of the corrugation 7. In FIG. 7 d, a weakened region is provided in such a way that the conductive material 13 or the bottom electrode is omitted or recessed not only in the area of the corrugation 7, but also in other areas of the horizontal section 5.

Preferably, the recess of the layer of conductive material 13 extends substantially along the length dimension of the planar membrane of a drawing depth (not visible) in the figures. However, it is preferred that conductive tracks or remaining conductive areas are provided, which ensure end-side contacts and continuous current flow in the top and/or bottom electrode. Thus, the recess of the top and/or bottom electrode can preferably be present substantially along the entire length dimension of the membrane, with the recess being interrupted by thin (less than 20 μm, preferably less than 10 μm) conductive areas or conductive tracks. In order to illustrate the formation of the weakened regions 19, the figures preferably show a cross-sectional plane along the length dimension at which the recess is visible.

FIG. 8 shows a schematic representation for a preferred provision of weakened regions 19 by providing recesses in an actuator layer 15. The weakened regions 19 are thus characterized by a reduction of a layer thickness of at least the layer 15 of an actuator material to 0% in some areas.

In the embodiments shown, a reduction in the actuation capacity of the actuator layer 15—for example a piezoelectric actuator layer 15—is achieved by structuring the actuator layer 15.

FIG. 8 a shows an embodiment in which the horizontal section 5 of the membrane exhibits a weakened region 19 over the area of the corrugation 7, in that an actuator layer 15 is omitted along the corrugation 19. The upper layer of conductive material 13, which acts as a top electrode, is also omitted in this area.

FIG. 8 b shows a section of a membrane with a corrugation 7 along a horizontal section 5. In the weakened region 19, the membrane comprises only a support layer 17, which is conductive and also acts as a bottom electrode. This provides a weakened region 19 in such a way that both the conductive material 13 or the top electrode and the actuator layer 15 are omitted not only in the area of the corrugation 7, but also in other areas of the horizontal section 5.

FIG. 8 c shows a section of a membrane with a corrugation 7 along a horizontal section 5. The membrane comprises a lower layer of a conductive material 13, which acts as a bottom electrode and support layer 17, and an upper layer of a conductive material 13, which forms a top electrode. The actuator layer 15 is omitted between the layers of electrically conductive material. Instead, an insulating layer 23 is inserted, which is formed by a dielectric material. In this embodiment, the actuation capacity of the membrane 1 is also reduced in the weakened region 19. Advantageously, replacing the actuator layer 15 with an insulating layer 23 makes it possible to maintain the overall thickness of the membrane 15. In addition, it may be preferred to use the dielectric layer to ensure mechanical stability of the membrane in the weakened region 19 as well.

FIG. 9 shows a schematic representation of weakened regions 19 by forming continuous openings 21.

FIG. 9 a shows the cross-section of a MEMS transducer that exhibits a membrane 1 comprising vertical sections 3 and horizontal sections 5. The membrane 1 extends in a horizontal direction along a support 2 on which the membrane 1 is suspended. The membrane 1 comprises a conductive support layer 17, which also acts as a bottom electrode, an actuator layer 15 and an upper layer of conductive material 13, which serves as a top electrode. In FIG. 9 a, dashed lines are also drawn on the horizontal sections 5, which are intended to symbolize that there are continuous openings as weakened regions 19 at these points of the horizontal sections 5. The weakened regions 19 are thus provided by reducing the layer thickness of all layers to 0% in some areas.

FIG. 9 b shows a top view of the MEMS transducer, whereby it can be seen that weakened regions 19 in the form of openings 21 are lined up in a row along the length dimension of the horizontal section 5. Despite the openings 21, the top and bottom electrodes are still conductive throughout the plane. The rigidity of the horizontal sections and/or vertical sections can therefore also be reduced locally by the provision of openings 21 in order to optimize the vibrational behavior of the membrane 1. The desired degree of rigidity reduction can be configured in particular by the geometric shape of the openings 21 and/or the number of openings 21.

FIG. 10 shows a schematic representation of a preferred embodiment of the MEMS transducer. As in the embodiment shown in FIG. 9, the membrane 1 comprises a conductive support layer 17, which also acts as a bottom electrode, an actuator layer 15 and an upper layer of conductive material 13, which serves as a top electrode. In the embodiment, the weakened regions 19 are provided by reducing the layer thickness of all layers comprising an actuator material, a conductive material or a support material to 0% of an initial thickness. Consequently, the weakened regions 19 are present as recesses in all layers 13, 15 and 17 of the membrane 1.

In order to avoid the formation of continuous openings through the membrane 1, it is preferred in the embodiment that the membrane 1 comprises a cover layer 25, preferably in the form of a polymer layer.

The provision of a cover layer 25, preferably in the form of a polymer layer, is advantageous in that an acoustic short circuit is reliably avoided regardless of the size of the recesses or openings to be provided. In the case of continuous openings in the membrane 1 with dimensions of approx. 5 μm or more, an acoustic short circuit can occur. An acoustic short circuit preferably means a reduction in sound radiation in the case of a loudspeaker or sound reception in the case of a microphone due to an undesirable pressure equalization between a rear and a front side. An acoustic short circuit can occur in particular when sound is emitted or received in the low-frequency range. Such pressure equalization can be avoided for the frequencies of desired applications by selecting small openings.

Advantageously, the use of a cover layer 25, for example in the form of a polymer layer, prevents the occurrence of an acoustic short circuit also for openings of any preferred size. This increases the design flexibility with regard to the provision of weakened regions, which are provided as openings by all layers comprising an actuator material, a support material or an electrically conductive material.

FIG. 10 shows that the cover layer 25 is applied to a front side of the membrane 1. Similarly, the cover layer 25 could also be applied to a rear side of the membrane 1. In the present case, the cover layer 25 extends substantially completely along the membrane 1. Alternatively, the cover layer could also be present as an interrupted, discontinuous layer, in which, however, at least one covering of the weakened regions 19 is ensured.

### LITERATURE

Bert Kaiser, Sergiu Langa, Lutz Ehrig, Michael Stolz, Hermann Schenk, Holger Conrad, Harald Schenk, Klaus Schimmanz and David Schuffenhauer, Concept and proof for an all-silicon MEMS microspeaker utilizing air chambers Microsystems & Nanoengineering volume 5, Article number: 43 (2019).
Iman Shahosseini, Elie LEFEUVRE, Johan Moulin, Marion Woytasik, Emile Martincic, et al. Electromagnetic MEMS Microspeaker for Portable Electronic Devices. Microsystem Technologies, Springer Verlag (Germany), 2013, pp. 10. <hal-01103612>.
F. Stoppel, C. Eisermann, S. Gu-Stoppel, D. Kaden, T. Giese and B. Wagner, NOVEL MEMBRANE-LESS TWO-WAY MEMS LOUDSPEAKER BASED ON PIEZOELECTRIC DUAL-CONCENTRIC ACTUATORS, Transducers 2017, Kaohsiung, TAIWAN, Jun. 18-22, 2017.
Zou, Quanbo, Zhijian Li, and Litian Liu. “Design and fabrication of silicon condenser microphone using corrugated diaphragm technique.” Journal of microelectromechanical systems 5.3 (1996): 197-204.

### REFERENCE LIST

1 Vibratable membrane
2 Carrier
3 Vertical section
5 Horizontal section
7 Corrugation
9 Substrate
11 Etch stop
13 Layer made of a conductive material
15 Layer made of an actuator material (actuator layer)
17 Layer made of a mechanical support material (support layer)
19 Weakened regions
21 Opening
23 Insulation layer
25 Cover layer, preferably in the form of a polymer layer

1. A MEMS transducer for interaction with a volume flow of a fluid comprising
a carrier and a vibratable membrane for generating or receiving pressure waves of the fluid in a vertical direction, which is attached to the carrier and is in contact with at least one electrode,
wherein the vibratable membrane exhibits vertical sections and horizontal sections, wherein the vertical sections are formed substantially parallel to the vertical direction, the vertical sections exhibit at least one layer comprising an actuator material and the horizontal sections connect the vertical sections to one another,
such that the vertical sections can be induced to vibrate horizontally by driving the at least one electrode or such that an electrical signal can be generated at the electrode when the vertical sections are induced to vibrate horizontally,
wherein the vertical sections and/or the horizontal sections exhibit one or more corrugations and/or weakened regions.

2. The MEMS transducer according to claim 1, wherein one or more corrugations and/or weakened regions are present along the horizontal sections, along the vertical sections and/or at connections between vertical sections and horizontal sections.

3. The MEMS transducer according to claim 1 wherein at least 1 or more corrugations and/or weakened regions are provided along a vertical section and/or a horizontal section.

4. The MEMS transducer according to claim 1, wherein the one or more corrugations exhibit a rectangular, trapezoidal, square, triangular, partially circular and/or round cross-section and/or the one or more corrugations exhibit a depth of 1 μm-100 μm, and/or a width of between approx. 0.5 μm-50 μm.

5. The MEMS transducer according to claim 1 wherein the one or more corrugations exhibit an aspect ratio of width to depth of 1:1 or more.

6. The MEMS transducer according to claim 1 wherein the horizontal sections and/or vertical sections are formed in a plurality of layers and wherein one or more weakened regions are created by a variation of the layer thickness of at least one layer.

7. The MEMS transducer according to claim 1, wherein the horizontal sections and/or vertical sections are formed in a plurality of layers and wherein one or more weakened regions are formed by a reduction in a region of a layer thickness of at least one layer to 0%, which is a layer comprising a conductive material, a layer comprising a supporting material and/or a layer comprising an actuator material.

8. The MEMS transducer according to claim 1, wherein a rigidity of the horizontal sections and/or vertical sections can be adjusted by the configuration of the one or more corrugations and/or weakened regions, in order to optimize the vibrational behavior of the vertical sections.

9. The MEMS transducer according to claim 1, wherein the introduction of one or more corrugations and/or weakened regions on the horizontal sections and/or vertical sections increases a rotational freedom of the vertical sections in order to optimize a vibrational behavior of the vertical sections.

10. The MEMS transducer according to claim 1, wherein the one or more corrugations are present in vertical sections and/or at connection points between vertical sections and horizontal sections, wherein the one or more corrugations can be provided by an etching process during a forming of vertical trenches for the vertical sections.

11. The MEMS transducer according to claim 1, wherein the MEMS transducer is a MEMS loudspeaker, wherein air volumes are present between the vertical sections, which are moved along a vertical emission direction by the horizontal vibrations to generate sound waves or the MEMS transducer is a MEMS microphone, wherein volumes of air are present between the vertical sections, which are moved along a vertical detection direction when sound waves are received.

12. The MEMS transducer according to claim 1, wherein the vibratable membrane comprises at least two layers, both layers comprising an actuator material and each being in contact with an electrode, and the horizontal vibrations can be generated by a change in shape of one layer relative to the other layer or the horizontal vibrations cause a change in shape of one layer relative to the other layer and generate an electrical signal.

13. The MEMS transducer according to claim 1, wherein the vibratable membrane comprises at least two layers, a first layer comprising an actuator material and a second layer comprising a mechanical support material, wherein at least the first layer comprising the actuator material is in contact with the electrode, such that horizontal vibrations can be generated by a change in shape of the actuator material relative to the mechanical support material or such that horizontal vibrations cause a change in shape of the actuator material in relation to the mechanical support material and generate an electrical signal.

14. The MEMS transducer according to claim 1, wherein the vibratable membrane comprises three layers, wherein an upper layer is formed by a conductive material and functions as a top electrode, a middle layer is formed by an actuator material and a lower layer is formed by a conductive material and functions as a bottom electrode, wherein the conductive material of the upper and/or lower layer is a mechanical support material.

15. A method for producing a MEMS transducer according to claim 1, comprising the following steps:
etching of a substrate, from a front side, to form a structure and to form corrugations,
optional application of an etch stop,
application of at least two layers, wherein at least a first layer comprises an actuator material and a second layer comprises a mechanical support material or at least two layers comprise an actuator material,
contacting of the first and/or second layer with an electrode, and
etching of the substrate, from the rear side, and optional removal of the etch stop,
such that the vibratable membrane is fixed to the carrier for effecting vibrations,
wherein the vibratable membrane exhibits vertical sections and horizontal sections, wherein the vertical sections are substantially parallel to the vertical direction and the horizontal sections connect the vertical sections to one another,
wherein the vertical sections and/or the horizontal sections exhibit one or more corrugations and/or weakened regions,
such that the vertical sections can be induced to vibrate horizontally by driving the electrode or an electrical signal can be generated at the electrode when the vertical sections are induced to vibrate horizontally.

16. The MEMS transducer according to claim 1, wherein the layer comprising the actuator material extends along the vertical sections and the horizontal sections of the membrane and is a continuous layer except for possible interruptions by weakened regions.

17. The MEMS transducer according to claim 6, wherein the layer thickness of the at least one layer is reduced to less than 70% of an initial layer thickness.

18. The MEMS transducer according to claim 8 wherein a rigidity of the horizontal sections and/or vertical sections is adjusted by the configuration of the one or more corrugations and/or weakened regions with regard to depth, width, layer thickness, geometry and/or number.

19. The method of claim 15, wherein the structure is a meander structure.

20. The method of claim 15, wherein one or more weakened regions are provided in the process of applying the at least two layers or by subsequent etching.
